(19) United States
(12) Patent Application Publication
(10) Pub. No.: US 2020/0087969 A1
(43) Pub. Date: Mar. 19, 2020

(54) OBJECT DETECTION SENSOR AND VEHICLE SAFETY DEVICE INCLUDING SAME

(71) Applicant: LG INNOTEK CO., LTD., Seoul (KR)

(72) Inventors: Sun Hwa LEE, Seoul (KR); Ki Chul CHANG, Seoul (KR); Chil Young JI, Seoul (KR)

(21) Appl. No.: 16/470,010

(22) PCT Filed: Dec. 15, 2017
(86) PCT No.: PCT/KR2017/014881

§ 371 Date: Jun. 14, 2019

(30) Foreign Application Priority Data
Dec. 15, 2016 (KR) 10-2016-0171766

(51) Int. Cl. E05F 15/48; G01V 3/38; G01R 27/26; B60J 10/76

(52) U.S. Cl. CPC E05F 15/48; G01V 3/38; E05Y 2900/55; B60J 10/76; G01R 27/2605

(57) ABSTRACT

An object detection sensor according to an embodiment comprises: a sensing layer including a resin and a carbon micro-coil inside the resin; and a sensing electrode embedded in the sensing layer, wherein the impedance value of the sensing layer changes on the basis of the reference impedance as an object approaches the pre-set sensing area.

This application is a U.S. National Stage Application under 35 U.S.C. § 371 of PCT Application No. PCT/KR2017/014881, filed Dec. 15, 2017, which claims priority to Korean Patent Application No. 10-2016-0171766, filed Dec. 15, 2016, whose entire disclosures are hereby incorporated by reference.

### TECHNICAL FIELD

The present invention relates to an object detection sensor, and more particularly to an object detection sensor capable of detecting an object through a carbon micro-coil (CMC) sensor using a CMC and controlling an operation of a window of a vehicle based on the detected object, and a vehicle safety device including the same.

### BACKGROUND ART

A vehicle is a device that moves in a direction desired by a user to board therein. Typically, cars may be cited as examples.

Various sensors and electronic devices tend to be provided for convenience of a user using the vehicle. In particular, various devices for the user's driving convenience have been developed.

Generally, the vehicle is provided with a window for circulating air inside the vehicle. Such a window is opened and closed by a power window method for a user's convenience. The power window method is a method in which the user completely opens or closes the window by a single switch operation.

That is, when the user operates a window switch once in a state in which the window is open, the window continues to operate until the window is completely closed without any additional operation by the user. However, the window operation method as described above continues to operate even if a part of the user's body exists on the opening and closing path of the window, and there is a problem that a safety accident occurs by this.

Accordingly, in recent years, sensors for stopping the operation of the window when an object is detected during the operation of the window to prevent the safety accident as described above have been developed.

At this time, there is an optical sensor in the sensor applied to the vehicle window.

The optical sensor is also referred to as a position sensing device (PSD), and may be commercialized by a measurement distance and has an advantage of convenience. However, since it is a device using light, it is affected by a surrounding environment, and there is a problem that a malfunction occurs by this.

That is, the optical sensor has a large difference in reflectance of a sensed material, but has no difference in a sensor output voltage. In the case of a light amount sensing operation, the optical sensor is greatly affected by the reflectance of an object.

In addition, the optical sensor needs analysis and database creation according to various usage environments due to a complicated calculation and algorithm.

In addition, although the optical sensor may measure up to 1 to 2 meters, there is a problem that accuracy in a near region such as an actual use environment in the vehicle is lowered. In addition, the optical sensor has a measurable angle, and has a problem in that the detection capability for an object of 120 degrees or more is lowered. In addition, external light (light using a similar frequency such as a fluorescent lamp) interferes with the optical sensor, and accordingly, there is a problem that an additional filter is required, thereby increasing a product cost and increasing a volume.

### DISCLOSURE

### Technical Problem

An embodiment of the present invention is directed to providing an object detection sensor and a vehicle safety device including the same that may accurately detect an object by applying a sensor to which a non-contact type carbon micro-coil (CMC) is applied and thereby control an operation of a window of a vehicle.

In addition, there is provided an object detection sensor and a vehicle safety device including the same capable of detecting the presence or absence of an object in a sensing region through a change in capacitance adopting a carbon micro-coil.

The technical problems to be solved in the proposed embodiments may not be limited to the technical problems mentioned above, and other technical subjects not mentioned may be clearly understood by those skilled in the art to which the embodiments proposed from the following description belong.

### Technical Solution

An object detection sensor according to an embodiment includes: a sensing layer including a resin and a carbon micro-coil in the resin; and a sensing electrode buried in the sensing layer, wherein in the sensing layer, an impedance value is changed as an object approaches in a pre-set sensing region based on a reference impedance value.

In addition, the object detection sensor further includes a substrate on which the sensing layer and the sensing electrode are disposed, and a protective layer surrounding the substrate, the sensing layer, and the sensing electrode.

Further, the object detection sensor further includes an elastic member including an insertion groove in which the sensing layer into which the sensing electrode is buried is inserted, wherein the elastic member is inserted into a window frame of a door body.

Furthermore, the resin configuring the sensing layer is a rubber resin of the elastic member inserted into the window frame of the door body, and the sensing layer is the elastic member in which the carbon micro-coil is mixed in the rubber resin.

In addition, the sensing electrode includes a copper wire inserted into the sensing layer.

In addition, the impedance value of the sensing layer decreases based on the reference impedance value as a target object approaches in the sensing region, and increases based on the reference impedance value as a foreign substance contacts with the sensing layer.

In addition, the carbon micro-coil is included in the sensing layer in a content of 0.1 to 10 wt %.

Further, a thickness of the sensing layer is in a range of 100 μm to 20 mm.

Furthermore, a ratio of an area of an upper surface of the sensing electrode to that of the substrate is in a range of 1% to 50%.

In addition, the sensing electrode has a thickness in a range of 25 μm to 2 mm.

Meanwhile, a vehicle safety device according to an embodiment includes: a door body; a window disposed in the door body; and a sensor disposed on the door body for sensing an object existing on an opening and closing path of the window, wherein the sensor includes a sensing layer including a resin and a carbon micro-coil in the resin and a sensing electrode buried into the sensing layer, and in the sensing layer, an impedance value is changed as the object approaches on the opening and closing path based on a reference impedance value.

In addition, the sensor further includes a substrate on an upper surface of which the sensing layer and the sensing electrode are disposed, and a protective layer surrounding the substrate, the sensing layer, and the sensing electrode.

Further, the sensor further includes an elastic member inserted into a window frame of the door body, and the sensing layer configuring the sensor is inserted into an insertion groove of the elastic member.

Furthermore, the resin configuring the sensing layer is a rubber resin of the elastic member inserted into the window frame of the door body, and the sensing layer forms the elastic member by mixing the carbon micro-coils in the rubber resin.

In addition, the sensing electrode includes a copper wire inserted into the sensing layer.

In addition, the vehicle safety device further includes a driving condition determining unit for determining a driving condition of the window based on a change in the impedance value, wherein the impedance value of the sensing layer decreases based on the reference impedance value as a target object approaches in a sensing region of the sensor and increases based on the reference impedance value as a foreign substance contacts with the sensing layer, and the driving condition determining unit determines the driving condition of the window only when the impedance value decreases based on the reference impedance value.

Further, the driving condition determining unit decreases an opening and closing speed of the window according to a degree of decrease of the impedance value.

In addition, the carbon micro-coil is included in the sensing layer in a content of 0.1 to 10 wt %, a thickness of the sensing layer is in a range of 100 μm to 20 mm, and a thickness of the sensing electrode is in a range of 25 μm to 2 mm.

### Advantageous Effects

According to an embodiment of the present invention, a sensor adopting a non-contact type carbon micro-coil (CMC) is applied to accurately detect an object, thereby preventing a safety accident by controlling an operation of a window of a vehicle.

In addition, according to an embodiment of the present invention, it is possible to increase a degree of freedom in an attachment position and area of a sensor by providing a low-cost, a slim thickness, and flexible type sensor in comparison with a conventional optical sensor.

In addition, according to an embodiment of the present invention, a conventional proximity sensor has a low accuracy in sensing objects other than metal and has a short detection distance, but a sensor of the present invention has an advantage that an accuracy for non-metals and human bodies is high.

Meanwhile, an object detection sensor of the present invention may be applied not only to a vehicle but also to a subway opening and closing safety door, an elevator proximity sensor, a rotary door safety sensor, and the like, and may also be used as a substitute sensor for a security sensor in a smart window and a distance sensor in a signature refrigerator.

### DESCRIPTION OF DRAWINGS

FIG. 1 is a view showing an appearance of a vehicle provided with a vehicle safety device according to an embodiment of the present invention.

FIG. 2 is an enlarged view of a door portion of the vehicle of FIG. 1.

FIG. 3 is a block diagram showing a vehicle safety device.

FIG. 4A is a view showing a detailed structure of an object detection sensor 200 according to a first embodiment of the present invention.

FIG. 4B is a view showing a modified structure of the object detection sensor 200 shown in FIG. 4A.

FIG. 5 is a view showing the sensing layer shown in FIG. 4A.

FIG. 6 is a plan view of the sensing electrode shown in FIG. 4A.

FIG. 7 is a view for describing a method of manufacturing the sensor 200 shown in FIG. 4A.

FIG. 8 is a view showing a detailed structure of an object detection sensor 300 according to a second embodiment of the present invention.

FIGS. 9 to 12 are views showing an operation principle of an object detection sensor 200 according to an embodiment of the present invention.

FIG. 13 is a view showing a specific configuration of the processor 170 shown in FIG. 3.

FIGS. 14 to 16 are views showing a change in a difference frequency value according to the first embodiment of the present invention.

FIG. 17 is a view showing a change in a difference frequency value according to the second embodiment of the present invention.

FIG. 18 is a graph showing change characteristics of a carbon micro-coil according to an embodiment of the present invention.

FIG. 19 is a flowchart showing steps of an operation method of a window 730 according to an embodiment of the present invention.

### MODES OF THE INVENTION

Hereinafter, exemplary embodiments of the present invention will be described in detail based on the accompanying drawings, wherein like reference numerals are used to designate identical or similar elements, and redundant description thereof will be omitted. The suffix “module” and “portion” of the components used in the following description are only given or mixed in consideration of ease of preparation of the description, and there is no meaning or role to be distinguished as it is from one another. Also, in the following description of the embodiments of the present invention, a detailed description of related arts will be omitted when it is determined that the gist of the embodiments disclosed herein may be obscured. Also, the accompanying drawings are included to provide a further understanding of the invention, are incorporated in, and constitute a part of this description, and it should be understood that the invention is intended to cover all modifications, equivalents, or alternatives falling within the spirit and scope of the invention.

Terms including ordinals, such as first, second, etc., may be used to describe various components, but the elements are not limited to these terms. The terms are used only for distinguishing one component from another.

When a component is referred to as being “connected” or “joined” to another component, it may be directly connected or joined to the other component, but it should be understood that other component may be present therebetween. When a component is referred to as being “directly connected” or “directly joined” to another component, it should be understood that other component may not be present therebetween.

A singular representation includes plural representations, unless the context clearly implies otherwise.

In the present application, terms such as “including” or “having” are used to specify the presence of features, numbers, steps, operations, components, parts, or combinations thereof described in the description. However, it should be understood that the terms do not preclude the presence or addition of one or more other features, numbers, steps, operations, components, parts, or combinations thereof.

A vehicle described in the present invention may be a concept including a vehicle, or a motorcycle. Hereinafter, a vehicle will be mainly described in terms of a vehicle.

The vehicle described in the present invention may be a concept including all of an internal combustion engine vehicle having an engine as a power source, a hybrid vehicle having an engine and an electric motor as a power source, and an electric vehicle having an electric motor as a power source.

In the following description, a left side of a vehicle refers to a left side in a traveling direction of the vehicle, and a right side of the vehicle refers to a right side in the traveling direction of the vehicle.

Unless otherwise mentioned in the following description, a left hand drive (LHD) vehicle will be mainly described.

Hereinafter, a vehicle safety device according to an embodiment will be described in detail based on the accompanying drawings.

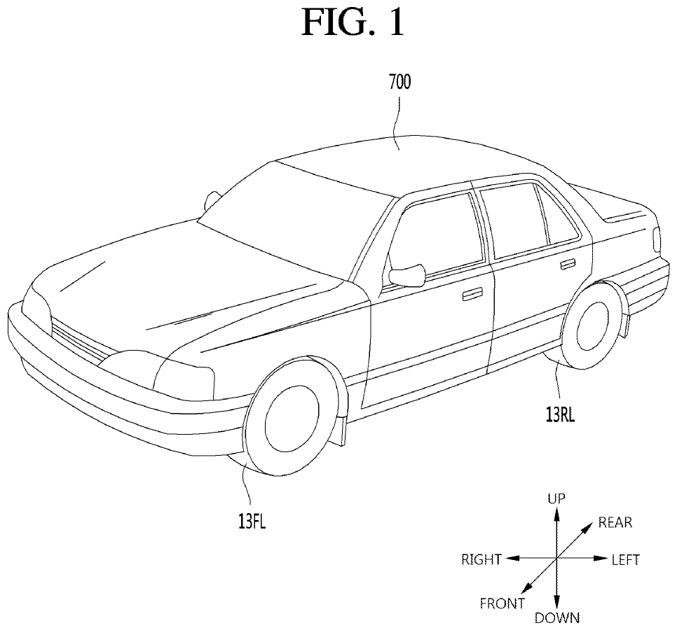

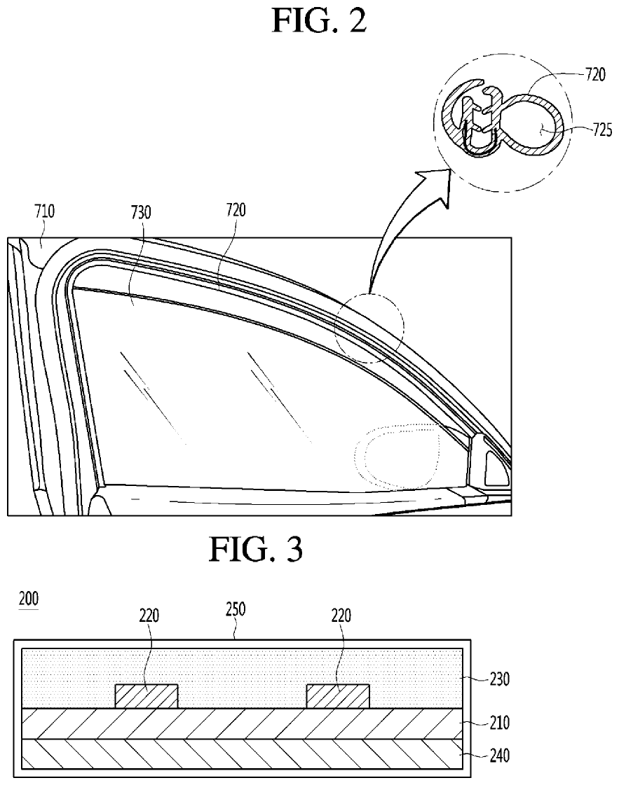

FIG. 1 is a view showing an appearance of a vehicle provided with a vehicle safety device according to an embodiment of the present invention, FIG. 2 is an enlarged view of a door portion of the vehicle of FIG. 1, and FIG. 3 is a block diagram showing a vehicle safety device.

Referring to FIGS. 1 to 3, a vehicle 700 according to an embodiment may include wheels 13FL and 13FR rotated by a power source, a driving operation unit (not shown) configured to control traveling of the vehicle, and a vehicle safety device 100.

Here, the vehicle safety device 100 is a separate device that may perform a function of assisting driving by transmitting and receiving necessary information through data communication with the vehicle 700, and a set of some units of the vehicle 700 may be defined as the vehicle safety device 100.

Some units of the vehicle safety device 100 may not be included in the vehicle safety device 100 but may be units of other devices mounted on a vehicle or the vehicle 700. Such units may be understood to be included in the vehicle safety device 100 by transmitting and receiving data via an interface unit of the vehicle safety device 100.

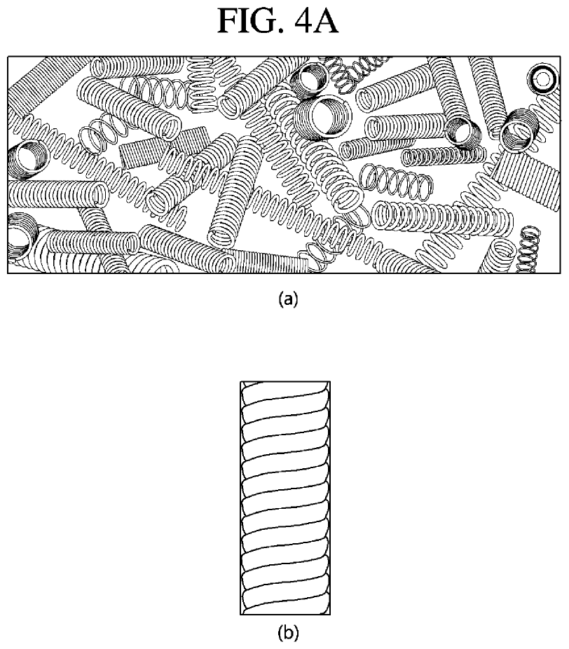

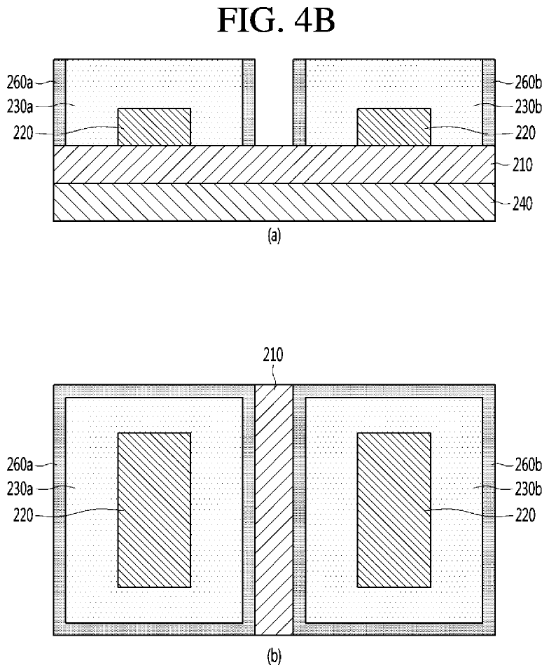

Although the vehicle safety device 100 according to an embodiment directly includes individual units shown in FIG. 4, it is also possible to use the units directly installed in the vehicle 700 via an interface unit 130, or to implement as a combination of the individual units directly installed in the vehicle 700.

Although the vehicle safety device 100 may be an idling restriction device that turns off an engine at the time of stopping, the following description will mainly focus on the aspect that the vehicle safety device 100 turns on the engine.

Specifically, such a vehicle safety device 100 may include an input unit 110, a communication unit 120, an interface unit 130, a memory 140, a visible light communication module 150, a camera 160, a processor 170, a display unit 180, an audio output unit 185, and a power supply unit 190.

First, the vehicle safety device 100 may include the input unit 110 configured to sense a user input. A user may input an execution input for turning on/off a function of the vehicle safety device or turning on/off a power of the vehicle safety device 100 via the input unit 110.

Such an input unit 110 may include at least one of a gesture input unit configured to sense a user gesture, a touch input unit configured to sense a touch, and a microphone configured to sense a voice input, and receive a user input.

Next, the vehicle safety device 100 may include the communication unit 120 configured to communicate with another vehicle 510, a terminal 600 and a server 500, and the like. The vehicle safety device 100 may receive navigation information and/or traffic information via the communication unit 120.

Specifically, the communication unit 120 may exchange data with the mobile terminal 600 or the server 500 in a wireless manner. Various data communication methods such as Bluetooth, WiFi, Direct WiFi, APiX, or NFC may be possible in a wireless data communication manner.

Next, the vehicle safety device 100 may include the interface unit 130 that receives vehicle-associated data or transmits a signal processed or generated by the processor 170 to an outside.

Specifically, the vehicle safety device 100 may receive navigation information and/or sensor information via the interface unit 130.

The interface unit 130 may perform data communication with a control unit (not shown), an audio video navigation (AVN) device 400, a sensor 200, and the like inside the vehicle in a wired or wireless communication manner.

The interface unit 130 may receive the navigation information by the data communication with the AVN device 400 and/or a separate navigation device.

In addition, the interface unit 130 may receive the sensor information from an object detection sensor 200. The sensor information is information measured via the object sensor 200, and may be simple voltage information.

In addition, the interface unit 130 may be connected to various sensors to receive information, and the received information may include at least one of traveling direction information of the vehicle 700, vehicle position information, vehicle speed information, acceleration information, vehicle tilt information, advance reverse information, fuel information, information on a distance from a preceding/rear vehicle, information on a distance between a vehicle and a lane, and turn signal information.

Accordingly, the interface unit 130 may receive the information by being connected with a heading sensor, a yaw sensor, a gyro sensor, a position module, a vehicle forward/reverse sensor, a wheel sensor, a vehicle speed sensor, a vehicle tilt sensor, a battery sensor, a fuel sensor, a tire sensor, a steering sensor based on rotation of a steering wheel, a vehicle interior temperature sensor, a vehicle interior humidity sensor, or the like. Meanwhile, the position module may include a GPS module for receiving GPS information.

The interface unit 130 may receive a user input received via the user input unit 110 of the vehicle 700.

The interface unit 130 may also receive various information acquired from the server 500.

Next, the memory 140 may store a variety of data for overall operation of the vehicle safety device 100, such as a program for processing or control of the processor 170.

Such a memory 140 may be various storage devices, which are implemented in a hardware manner, such as ROM, RAM, EPROM, flash drive and hard drive.

Next, the vehicle safety device 100 may include a monitoring unit (150) for capturing an image inside the vehicle.

Specifically, the monitoring unit (150) may detect and acquire biometric information of the user.

Such biometric information may include image information capturing the user, fingerprint information, iris-scan information, retina-scan information, hand geometry information, facial recognition information, and voice recognition information. That is, the monitoring unit 150 may include a sensor for sensing the biometric information of the user.

In addition, the monitoring unit 150 may acquire an image for biometrics of the user. That is, the monitoring unit 150 may include an image acquisition module disposed inside the vehicle.

Next, the vehicle safety device 100 may include a camera 160 for acquiring a surroundings image of the vehicle. In addition, the acquired surroundings image of the vehicle may be processed by the processor 170 and used to generate image information.

Here, the image information may include at least one of a captured object, a type of the object, a traffic signal information displayed by the object, a distance between the object and the vehicle, and a position of the object.

In particular, the processor 170 is connected to the object detection sensor 200 via the interface unit 130, and receives a signal output from the object detection sensor 200.

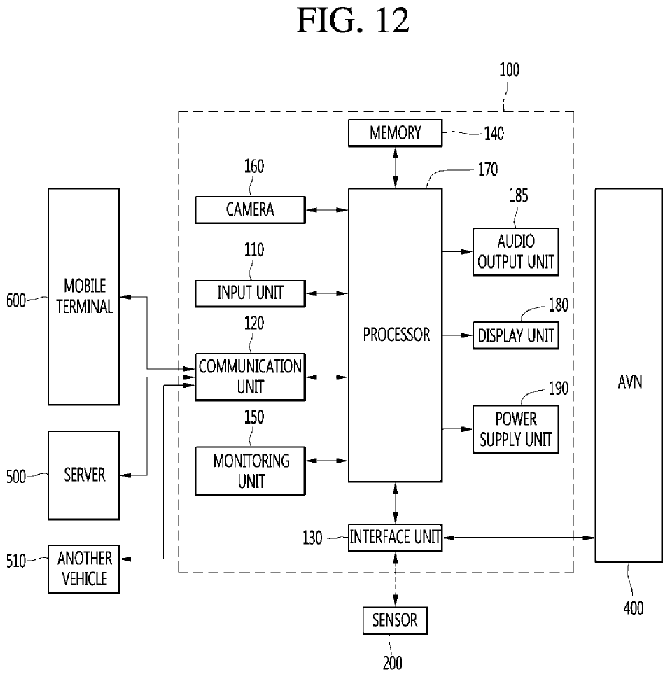

At this time, the processor 170 may be configured as a simple analog output circuit as shown in FIG. 12, and alternatively, may include elements as shown in FIG. 13.

That is, the processor 170 may be a circuit that simply amplifies the output signal of the object detection sensor 200 and outputs a switching signal. Alternatively, the processor 170 analyzes the signal obtained via the object detection sensor 200 and a distance to the object detected by the object detection sensor 200, and may include a plurality of elements that determine operating conditions of the window based on the analyzed distance.

A detailed operation of the processor 170 will be described in more detail below.

Meanwhile, referring to FIG. 2, an opening and closing door disposed in a plurality of regions of the vehicle 700 is provided. The opening and closing door includes a door body 710 and an elastic member 720 inserted into a window frame of the door body 710 to protect a window 730.

At this time, as shown in the drawing, the elastic member 720 has a insertion groove 725 formed therein, and when the window 730 is opened and closed, the elastic member 720 protects the window 730 based on the elastic force generated by the insertion groove 725.

Meanwhile, in the present invention, the object detection sensor 200 is disposed in the insertion groove 725 of the elastic member 720. In addition, the object detection sensor 200 senses an object existing in a predetermined sensing region on the disposed region, and outputs sensing information of the object.

Since the elastic member 720 is applied to a general vehicle at present, a detailed description thereof will be omitted. In the present invention, the object detection sensor 200 is disposed in the insertion groove of the elastic member 720 such that together with the window, the object detection sensor 200 is also protected by the elastic member 720.

Meanwhile, the object detection sensor 200 may be disposed at a position other than the insertion groove of the elastic member 720. That is, the object detection sensor 200 may be disposed on an opening and closing path of the window of the door body 710 separately from the elastic member 720.

In addition, alternatively, in the case of a position in which the presence or absence of an object on the opening and closing path of the window may be detected, it is possible to change a mounting position of the object detection sensor 200 within a range that does not deviate from the essential characteristics by a person having ordinary skill in the art to which the embodiment belongs.

Hereinafter, an object detection sensor 200 according to an embodiment of the present invention will be described in more detail based on the accompanying drawings.

FIG. 4A is a view showing a detailed structure of an object detection sensor 200 according to a first embodiment of the present invention.

Referring to FIG. 4A, the sensor 200 includes a substrate 210, a sensing electrode 220, a sensing layer 230, a driving unit 240, and a protective layer 250.

Here, the object detection sensor 200 of the present invention is exemplified as one package including the driving unit 240, but the driving unit 240 may be omitted in a package configuring the object detection sensor 200. In other words, the driving unit 240 may be disposed outside the object detection sensor 200 to be connected to the sensing electrode 220 of the object detection sensor 200 and to be replaced with a configuration of the vehicle safety device 100.

The object detection sensor 200 is disposed in the elastic member 720 of the door body 710, and senses a change in impedance according to whether an object approaches or not on the opening and closing path of the window 730, thereby outputting a sensing signal for determining an operating state of the window 730.

At this time, the object detection sensor 200 is disposed in an insertion groove 725 of the elastic member 720. In other words, the protective layer 250 configuring the object detection sensor 200 may be replaced with the elastic member 720.

In other words, the sensing electrode 220 and the sensing layer 230 are disposed on the substrate 210 to configure a sensor package in a form of one patch. Accordingly, the sensor package configured as described above may be disposed in the insertion groove 725 of the elastic member 720. Accordingly, the protective layer 250 of the object detection sensor 200 may be eliminated, thereby protected by the elastic member 720.

The substrate 210 is a base substrate on which the sensing electrode 220, the sensing layer 230, and the driving unit 240 are mounted.

The sensing electrode 220 is formed on the substrate 210. The sensing electrode 220 is formed on an upper surface of the substrate 210 while being buried by the sensing layer 230.

The sensing electrode 220 is formed in plural, and senses a varying impedance as the sensing layer 230 reacts with an object positioned adjacent to the sensing layer 230.

Preferably, the sensing electrode 220 may include a first sensing electrode having a positive polarity and a second sensing electrode having a negative polarity.

The sensing layer 230 is formed on the substrate 210 and is formed to bury the upper surface of the substrate 210 and the sensing electrode 220.

Preferably, the sensing layer 230 is formed on the substrate 210 on which the sensing electrode 220 is formed while having a predetermined thickness.

The sensing layer 230 is formed of a conductive material, and has a property in which the impedance varies according to approach of an external object.

Preferably, the sensing layer 230 is a carbon micro-coil (CMC) having a spring shape. That is, the sensing layer 230 is formed by depositing at least one of hydrocarbons such as acetylene, methane, propane, and benzene on the substrate 21 by a chemical vapor deposition (CVD) process.

In addition, otherwise, the sensing layer 230 may be manufactured using a metal catalyst based on nickel or nickel-iron.

As described above, the CMC may have a shape which is not straight, but is curled like a pig tail as shown in FIG, 5 and is amorphous carbon fiber with a unique structure that a fiber material may not have. Further, the CMC has a superelasticity, which extends to a length, which is ten times or more that of an original coil.

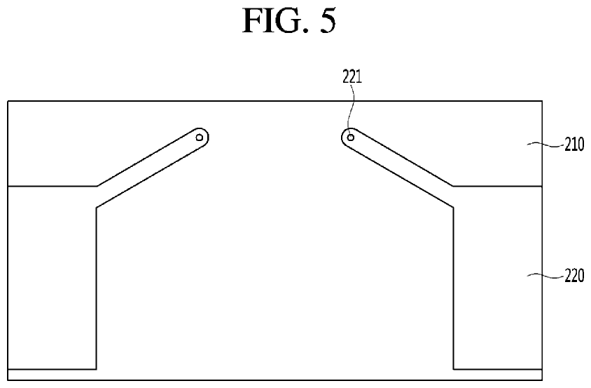

(a) of FIG. 5 shows a carbon micro-coil formed in a detection layer 230, and (b) of FIG. 5 is a detailed view of the carbon micro-coil.

Morphology of the sensing layer 230 has a 3D-helical/spiral structure, and the crystal structure is amorphous.

In other words, the sensing layer 230 as described above is formed by growing carbon fibers into a coil shape, and accordingly, the sensing layer 230 has a cross-sectional structure in which carbon fibers are grown in a coil shape.

That is, in the sensing layer 230, a change in impedance occurs as an object is present at a position adjacent to a region in which the object detection sensor 200 is mounted.

Meanwhile, the sensing layer 230 as described above is manufactured by mixing the carbon micro-coil (CMC) in curing agent and epoxy resin. In addition, in the CMC, a change in impedance occurs due to interaction between the CMCs according to concentration of the solution among the mixtures mixed as described above.

Here, the CMC has a different property from that of a carbon nano tube. That is, the carbon nano tube has a carbon-bonded form in a hexagonal shape in a form of nano tube.

However, the CMC of the present invention does not have a carbon-to-carbon structural form but has a form in which carbon is grown to a micro unit coil using a catalyst.

The above-described carbon nano tube obtains a specific measurement value by using a change in impedance from a conductor to a non-conductor by using a characteristic of becoming a conductor or a non-conductor depending on a type of bonding of an element itself.

However, in the case of the CMC, in a form of a coil manufactured by micro unit carbon, due to a characteristic of L varying according to extension and contraction of the coil due to a change in force or dielectric constant and a characteristic of C depending on a distance between the respective CMCs, the impedance changes according to an interaction between the CMCs.

That is, although the CMC itself has a property of a conductor, since the above-described curing agent, epoxy resin, or the like has a non-conductive property, the CMC has an inherent capacitance value, and when a distance between the CMCs changes by a change in the above-described force or dielectric constant, the characteristics of the capacitance value changes accordingly.

In addition, the sensing electrode 22 senses a change in impedance of the reaction layer 23, thereby transmitting a sensing signal corresponding to the change in impedance to the driving unit 240.

The driving unit 240 is selectively formed on a lower surface of the substrate 210, and accordingly, the driving unit 240 senses a change in the concentration of the solution and the concentration according to the sensing signal transmitted through the sensing electrode 220, and outputs information on the sensed concentration.

That is, in general, REAL TERM of impedance is resistance, POSITIVE IMAGINARY TERM is inductance, and NEGATIVE IMAGINARY TERM is capacitance, and the impedance consists of a summation of the resistance, inductance and capacitance.

Therefore, the object detection sensor 200, like a general resistor, an inductor, and a capacitor, also needs a pair of sensing electrodes 220 so as to sense a change in impedance generated in the sensing layer 230. The sensing electrode 220 functions to connect the sensing layer 230 and the driving unit 240 while optimizing the sensing characteristics of the sensing layer 230.

Here, when an object is present at a region adjacent to the object detection sensor 200, a capacitance of the sensing layer 230 is increased, accordingly a resistance value and an inductance value are decreased as opposed to the capacitance.

At this time, the sensed impedance value is a summation of the resistance value, the inductance value, and the capacitance value, and thus the impedance value is linearly decreased depending on a degree of the force or dielectric constant applied to the surface.

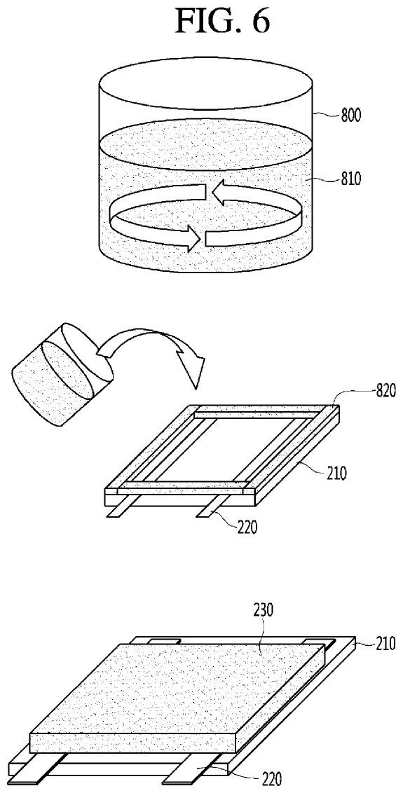

At this time, the sensing electrode 220 has a structure as shown in FIG. 6 and is formed on the substrate 210.

The sensing electrode 220 may include a first electrode portion formed in an edge region of the substrate 210 and a second electrode portion extending from one end of the first electrode portion to a central region of the substrate and having a predetermined inclination angle with respect to one end of the first electrode portion.

That is, an impedance change state of the sensing layer 230 varies depending on a shape of the sensing electrode 220.

Accordingly, in the present invention, the sensing electrode 220 including the first electrode portion and the second electrode portion as described above is formed on the substrate 210 in order to optimally adjust the impedance change state of the sensing layer 230.

Meanwhile, a via 221 is formed at a lower portion of one end of the second electrode portion.

The via 221 is formed by baring a through hole penetrating upper and lower surfaces of the substrate 210 with a metal material.

One end of the via 221 is connected to the sensing electrode 220 by passing through the substrate 210, and the other end of the via 221 is connected to a driving unit 240 attached to the lower surface of the substrate 210.

Meanwhile, the driving unit 240 is provided with an analog front end (AFE) which is connected to the sensing electrode 22.

Meanwhile, a shape of the sensing electrode is merely one embodiment, and preferably, the sensing electrode may have a spiral structure or a radial structure in which the sensing electrode is rotated in a predetermined number of times.

In addition, when the sensing electrode has the spiral structure or the radial structure, a line width, a pitch, and a number of turns of the sensing electrode may be determined as a condition for maximizing performance of the sensor.

At this time, the AFE performs a differential amplification function, and there is a difference in the state of change of the impedance according to the generation of the specific material depending on whether the differential amplification is positive or negative.

Accordingly, the driving unit 240 senses a state of change of the impedance value based on a reference value according to the differential amplification state, and when a degree of the state of change deviates from a critical value, it may be determined that an object exists on the opening and closing path of the window 730.

FIG. 4B is a view showing a modified structure of the object detection sensor 200 shown in FIG. 4A.

The object detection sensor 200 shown in FIG. 4B differs in the structure of the sensing layer 230 from FIG. 4A. That is, in FIG. 4A, the sensing layers covering a plurality of electrodes are formed as one common layer. On the contrary, the object detection sensor shown in FIG. 4B has a structure in which the sensing layers covering a plurality of electrodes are physically separated from each other.

(a) of FIG. 4B is a cross-sectional view of the object detection sensor, and (b) of FIG. 4B is a plan view thereof.

Referring to FIG. 4B, the sensing layers covering the plurality of electrodes may be physically separated from each other. That is, the sensing layer may include a first sensing layer 230a covering one electrode of the plurality of electrodes and a second sensing layer 230b covering the other electrode of the plurality of electrodes.

In addition, the first sensing layer 230a and the second sensing layer 230b may be physically separated from each other.

At this time, the first sensing layer 230a and the second sensing layer 230b may include partition wall portions 260a and 260b to be physically separated as described above. That is, the first sensing layer 230a and the second sensing layer 230b may be disposed only in a specific region via a jig (not shown), and the jig may be removed after the sensing layer is formed. In addition, the first sensing layer 230a and the second sensing layer 230b may include the partition wall portions 260a and 260b serving as the jig, and the partition wall portions 260a and 260b serving as the jig may still remain as one element of the sensor after the sensing layer has been formed.

When the partition wall portions 260a and 260b are included, in the object detection sensor, each of regions in which a plurality of electrodes are disposed is partitioned by the partition wall portions 260a and 260b.

That is, the partition wall portions 260a and 260b include a first partition wall portion 260a surrounding one of the plurality of sensing electrodes 220 and a second partition wall portion 260b surrounding the other one of the sensing electrode 220.

In addition, the sensing layer 230 includes a first sensing layer 230a disposed in the first partition wall portion 260a and covering the one of the sensing electrodes, and a second sensing layer 230b disposed in the second partition wall portion 260b and covering the other one of the sensing electrodes.

Accordingly, each region in which the plurality of sensing electrodes are disposed is separated by the partition wall portion. In addition, the sensing layers 230a and 230b may be disposed in each region partitioned by the partition wall portion to be physically separated from each other.

Accordingly, the sensing layers 230a and 230b covering the plurality of sensing electrodes may be physically separated from each other by the partition wall portions 260a and 260b, thereby minimizing signal interference occurring between the sensing electrodes.

The partition wall portions 260a and 260b allow each of the sensing layers to be disposed only on a designated sensing region while physically separating the sensing layers 230a and 230b from each other, and surround the sensing layers 230a and 230b in order to match the flatness of the sensing layers 230a and 230b. That is, the partition wall portions 260a and 260b may function as a dam for dispensing while maintaining the flatness of an upper surface of the sensing layers 230a and 230b, and may be formed of silicone for this.

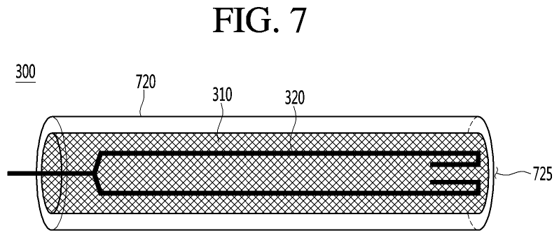

FIG. 7 is a view for describing a method of manufacturing the sensor 200 shown in FIG. 4A.

Referring to FIG. 7, first, a solution 810 for forming the sensing layer 230 is manufactured in a plating tank 800.

The solution 810 may be made of a carbon micro-coil. At this time, the solution 810 may include only the carbon micro-coil, or alternately, a resin and dispersant may be further added.

As described above, in a first step, a carbon micro-coil material and a resin are added and mixed in the plating tank 800, and accordingly, the dispersant is further added and dispersed therein. The dispersant is for uniformly dispersing the solution on a substrate 210.

At this time, the carbon micro-coil may be included in the solution 810 with a content of 0.1 to 10 wt %. That is, when the content of the carbon micro-coil is 10 wt % or more, a R value is further influenced.

In addition, more preferably, the carbon micro-coil may determine a large electromagnetic field value as a proximity sensor, but shows the highest efficiency at 5 wt %, so that the carbon micro-coil may be configured with a content of 5 wt % in the solution 810.

In addition, a base material to be mixed with the carbon micro-coil may be a silicone-based epoxy resin, or alternatively, a rubber-based resin may be used.

In other words, the solution 810 includes the carbon micro-coil in the resin, and at this time, the carbon micro-coil may have a content of 0.1 to 10 wt %.

Next, a substrate 210 is prepared, and a sensing electrode 220 is formed on the prepared substrate 210.

The sensing electrode 220 is formed in plural, and have a planar structure as shown in FIG. 6. At this time, it is preferable that the sensing electrode is designed so as to have a large reference impedance value or a large capacitance value, but it is necessary to avoid a design of distorting or reducing a frequency of the carbon micro-coil itself in an antenna form.

At this time, an area ratio of the substrate 210 to the sensing electrode 220 may be within a range of 1% to 50%, and the sensing electrode 220 may be formed of copper (Cu), platinum (Pt), or a metal electrode.

In addition, a thickness of the sensing electrode 220 is in a range of 25 μm to 2 mm.

Next, a frame 820 is formed in an edge region of the substrate 210. The frame 820 is formed on the substrate 210 while covering the edge region of the substrate 210 and exposing a central region of the substrate 210.

Next, the manufactured solution 810 is injected into the frame 820 of the substrate 210.

Then, the sensing layer 230 is formed based on the injected solution 810 through a curing process.

At this time, the curing process may be performed at a temperature of 120° C. for 30 minutes.

Hereinafter, a driving principle of the object detection sensor 200 will be described in more detail.

As described above, the sensing electrode 220 is buried in the sensing layer 230 composed of the carbon micro-coil. In addition, the sensing electrode 220 is connected to the driving unit 240 mounted on a lower portion of the substrate 210 through a via 221.

At this time, the sensing layer 230 itself may sense whether an object approaches or not depending on an impedance change amount, and measurement sensitivity also varies depending on a shape of the sensing electrode 220. Accordingly, in an embodiment, the sensing electrode 220 having the planar shape as described above is formed.

Therefore, in the embodiment, optimization of various factors such as a composition by adjusting a content ratio of the carbon micro-coil, optimized electrode shape, and mounting position of the driving unit 240, and the like is important.

In addition, as described above, the impedance is composed of a real part (real) and an imaginary part (reactance), and the imaginary part is composed of a positive imaginary part (inductive) and a negative imaginary part (capacitive). At this point, the sensor 130 including the carbon micro-coil is measured using two characteristic changes of the positive imaginary part (inductive) and negative imaginary part (capacitive).

That is, the object detection sensor 200 has a sensing region of a predetermined range, and the sensing region may be determined by the electromagnetic field generated by the object detection sensor 200. At this time, the carbon micro-coil (CMC), as the name describes, is composed of a very fine collection of coils, and is also a dielectric having a dielectric constant.

At this time, as an object approaches, an inductive element changes, that is, a characteristic change of the CMC occurs, and accordingly, whether the object approaches or not is measured by a capacitive change due to a change in a dielectric constant.

At this time, a real part (real) may be adjusted depending on an area of the sensing layer 23, and when the object exists, as described above, an impedance value changes due to changes in inductive and capacitive values.

Accordingly, in an embodiment, a change of an impedance value according to a variation of an inductive and capacitive value of the sensor 130 as described above is detected to sense whether the object approaches or not.

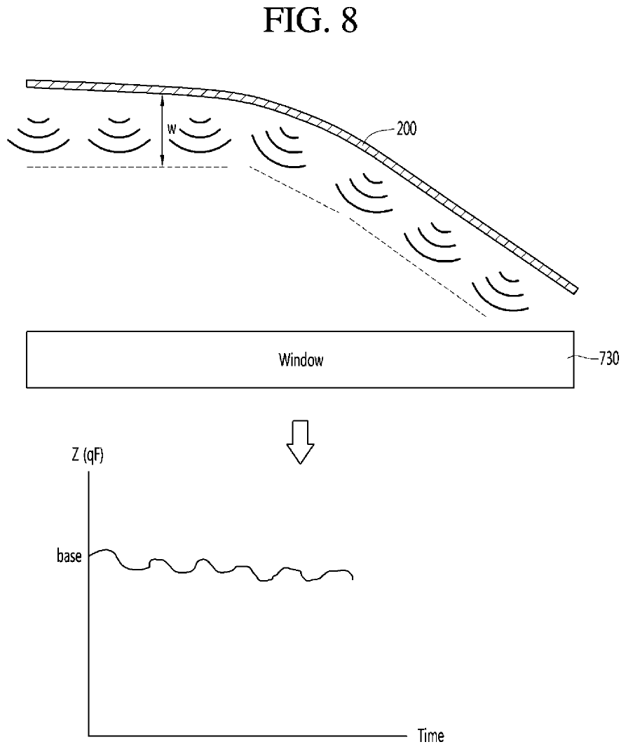

FIG. 8 is a view showing a detailed structure of an object detection sensor 300 according to a second embodiment of the present invention.

Referring to FIG. 8, the object detection sensor 300 includes an elastic member 720 including an insertion groove 725, a sensing layer 310 filling the insertion groove 725 of the elastic member 720, and a sensing electrode 320 buried in the sensing layer 310.

That is, in the present invention, the object detection sensor 200 as shown in FIG. 4A may be manufactured in a patch form to insert into or attach to a region which is in contact with an actual window 730 of a window frame rubber of a general vehicle.

Alternatively, in the present invention, the sensing electrode 320 formed of a copper wire is inserted into the insertion groove 725 of the elastic member 720 of the window frame rubber as described above, and accordingly, the sensing layer 310 including a carbon micro-coil and a resin may be formed so as to fill the insertion groove 725.

Alternatively, in the present invention, the elastic member 720 itself may be manufactured as the object detection sensor 200.

In other words, the elastic member 720 is made of a rubber-based resin. Accordingly, when the elastic member 720 is manufactured, carbon micro-coil powder is mixed in the rubber-based resin, and the rubber-based resin mixed with the carbon micro-coil powder is used to manufacture the elastic member 720, and the elastic member 720 itself may be used as the object detection sensor 200.

That is, the object detection sensor 200 operates as a simple switch sensor for controlling a driving of the window 730, not for acquiring a specific signal value. Accordingly, it is not necessary to acquire the specific signal value, but it is only necessary to know whether there is a change in the signal value. Therefore, in the above-described case, the elastic member 720 itself may be manufactured and used as the object detection sensor 200 as described above. At this time, when the elastic member 720 is manufactured, an electrode for checking an impedance change state of the elastic member 720 may be manufactured to be inserted into the elastic member 720.

Hereinafter, an actual implementation example of the object detection sensor according to the present invention will be described.

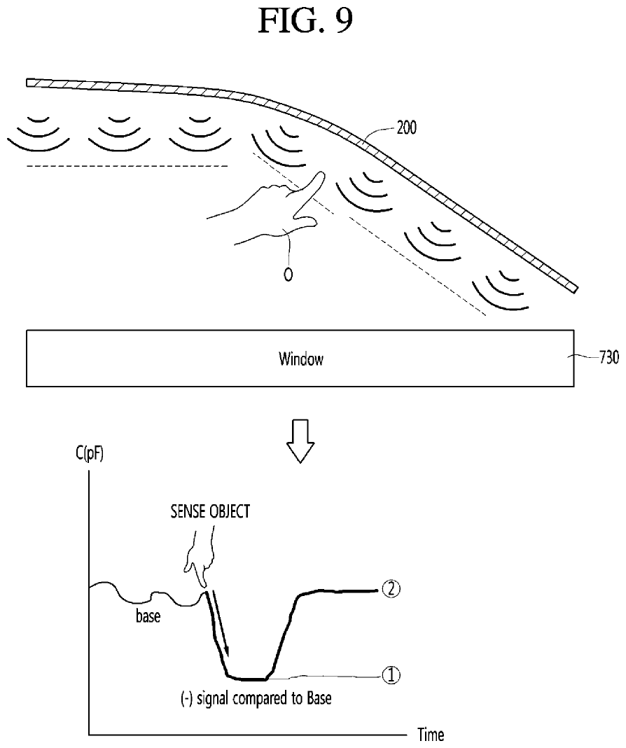

FIGS. 9 to 12 are views showing an operation principle of an object detection sensor 200 according to an embodiment of the present invention.

First, referring to FIG. 9, the object detection sensor 200 is installed in a door body 710 as described above, and accordingly, senses an object present on an opening and closing path of a window 730 when the window 730 is operated.

At this time, the object detection sensor 200 has a sensing region W of a predetermined range, and a characteristic change of a sensing layer occurs as an object is present in the sensing region W.

In addition, when the object is not present in the sensing region W, impedance of the object detection sensor 200 has a specific reference value (base). At this time, the specific reference value is not a fixed value, but may vary within a predetermined range. In other words, the reference value has a value of A±α.

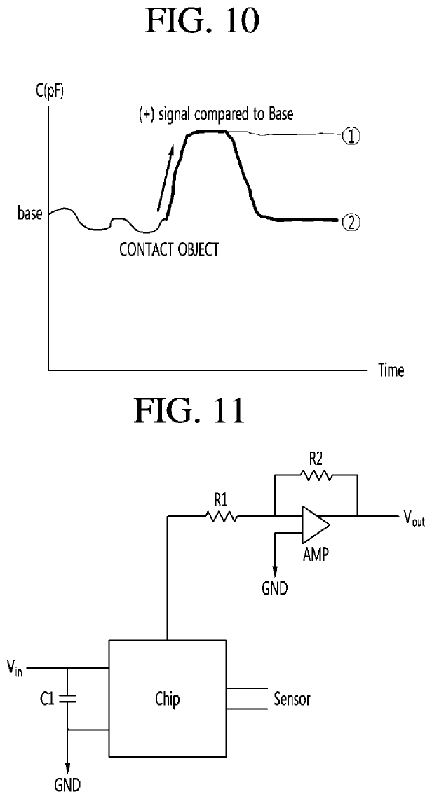

Next, referring to FIG. 10, in the state as described above, when an object O approaches into the sensing region W of the object detection sensor 200, a change in a capacitance value of the object detection sensor 200 occurs.

That is, the capacitance value has a negative signal compared to the reference value as an object is sensed in the sensing region W. In other words, the capacitance value of the object detection sensor 200 is reduced based on the reference value as the object O approaches into the sensing region W.

Accordingly, in the present invention, when the capacitance value is reduced to a predetermined threshold value or less based on the reference value, by using characteristics of the sensing layer of the object detection sensor 200, it is determined that the object O approaches into the sensing region W, and accordingly, a signal for stopping an operation of the window 730 is output.

At this time, when the object continues to stay in the sensing region even after the object is sensed, as in the state \textcircled{1}, the capacitance value is maintained at a value reduced to the predetermined threshold value or less based on the reference value. On the other hand, when the object deviates from the sensing region after the object is sensed, as in the state \textcircled{2}, the capacitance value is returned to the reference value.

Meanwhile, the object detection sensor 200 also reacts to a foreign substance (water such as rainwater) which is not an object such as a human body. At this time, when the capacitance value of the object detection sensor 200 changes due to the foreign substance, the operation of the window 730 should not be stopped.

Accordingly, in the present invention, when the foreign substance is sensed, the operation of the window 730 is controlled by distinguishing a situation in which the object such as the human body is sensed.

That is, when the object such as the human body approaches on the sensing region of the object detection sensor 200, the capacitance value of the object detection sensor 200 is reduced compared to the reference value.

However, when an object such as the foreign substance contacts on the sensing region of the object detection sensor 200, the capacitance value of the object detection sensor 200 increases compared to the reference value.

In other words, as shown in FIG. 11, the capacitance value has a positive signal compared to the reference value as the foreign substance contacts the object detection sensor 200. In other words, the capacitance value of the object detection sensor 200 increases based on the reference value as the foreign substance contacts.

Accordingly, in the present invention, when the capacitance value is increased to a predetermined threshold value or more based on the reference value, by using the characteristics of the sensing layer of the object detection sensor 200, it is determined that the foreign substance contacts to the object detection sensor 200, and accordingly, the operation of the window 730 is continuously performed.

At this time, when the contact of the foreign substance is still maintained even after the foreign substance has contacted, as in the state \textcircled{1}, the capacitance value is maintained at a value increased to the predetermined threshold value or more based on the reference value. On the other hand, when the foreign substance is removed after the foreign substance has contacted, as in the state \textcircled{2}, the capacitance value is returned to the reference value.

FIG. 12 is a circuit diagram showing one example of a driving unit according to an embodiment of the present invention.

Referring to FIG. 12, the driving unit includes a first capacitor C1, a first resistor R1, a second resistor R2, an amplifier AMP, and a chip.

The chip is connected to a sensing electrode 220 of the object detection sensor 200, and accordingly, receives a sensed signal from the sensing electrode 220. At this time, the chip outputs an impedance value of the sensing layer of the object detection sensor 200 based on the signal received from the sensing electrode 220.

The first capacitor C1 is a smoothing circuit, and accordingly smoothes an input power supply Vin to remove an AC signal to ground, thereby providing only a DC signal to the chip.

The first resistor R1 and the second resistor R2 are disposed for operational stability of a circuit.

The amplifier AMP receives a signal output from the chip, and accordingly outputs an optional output voltage Vout depending on a magnitude of the signal.

In other words, one terminal of the amplifier AMP is connected to ground, and the other terminal is connected to the chip. Therefore, when the signal received via the other terminal is equal to or greater than a predetermined reference value, the amplifier removes the signal to ground and does not generate the output voltage Vout. In addition, when the signal received via the other terminal decreases to a predetermined threshold value or less based on the reference value, the amplifier generates the output voltage Vout based on the signal. The output voltage may be connected to a window driver (not shown) for controlling an operation of the window 730, and accordingly, when the output voltage is received, the window driver recognizes that an object presents on the opening and closing path of the window and stops the operation of the window.

As described above, the driving circuit, which generates or does not generate the output voltage only for whether or not a simple object as described above is sensed, may be disposed at the output terminal of the object detection sensor 200, and accordingly, the object detection sensor 200 may operate as a simple switch.

Alternatively, in the present invention, the output value of the object detection sensor 200 is accurately recognized and an approach degree of the object detection sensor 200 is grasped based on the recognized output value so as not to simply stop the operation of the window 730 but to determine specific operating conditions.

For this, a processor 170 is connected to the object detection sensor 200, and outputs different digital values (ADC value) according to the characteristic change of the object detection sensor 200.

At this time, the value output via the processor 170 may change linearly depending on whether the object approaches or not and an approach distance. For example, the digital value has a value (reference value) of zero when the object does not approach, and gradually decreases depending on whether the object approaches or not and the approach degree.

Accordingly, in the present invention, a value varying according to the approach degree of the object is stored in a memory, and a distance to the object corresponding to the digital value may be calculated by using the digital value output through the processor 170.

FIG. 13 is a view showing a specific configuration of the processor 170 shown in FIG. 3.

Referring to FIG. 13, the processor 170 includes a first frequency generator 171, a second frequency generator 172, a difference frequency generator 173, a filter 174, and an analog-to-digital converter 175.

The first frequency generator 171 is connected to the object detection sensor 200, and generates a first frequency according to an impedance change of the object detection sensor 200.

The first frequency generator 171 may be an LC oscillation circuit.

Preferably, the first frequency generator 171 is configured so as to generate an oscillation frequency that varies according to a change in an inductance value or a capacitance value of the carbon micro-coil by using a carbon micro-coil and a capacitor configuring the sensing layer 310.

That is, the first frequency generator 171 oscillates the oscillation frequency of the object detection sensor 200 by using the carbon fine-coil of the object detection sensor 200.

In other words, the inductance value of the carbon micro-coil and the capacitance value of the capacitor configuring the object detection sensor 200 determine the oscillation frequency of the first frequency generator 171.

The second frequency generator 172 may be a reference oscillator, and generates a second frequency corresponding to a reference oscillation frequency.

At this time, the first frequency generated by the first frequency generator 171 may have a minute change, and accordingly, the filter 174 is configured as a low-pass filter in the first embodiment of the present invention.

Hereinafter, it will be described on the assumption that the filter 174 is configured as a low-pass filter.

At this time, the first frequency generated in the absence of an object on a sensing region of the object detection sensor 200 and the second frequency generated in the second frequency generator 172 may be set so as to have the same value.

In addition, when an object approaches the sensing region of the object detection sensor 200, a difference between the first frequency and the second frequency increases depending on an approach degree of the object, and it is possible to determine whether the object approaches or not and a distance to the object based on the increasing difference value.

At this time, when the inductance of the carbon micro-coil included in the object detection sensor 200 is L and the capacitance of the capacitor is C, a first frequency ω₀ generated by the first frequency generator 171 is expressed as Equation 1.

$${ω}_{o} = \frac{1}{2 π \sqrt{LC}} \qquad [ Equation 1 ]$$

In addition, a first voltage value V₀ corresponding to the first frequency generated by the first frequency generator 171 is expressed as the following Equation 2.

$${V}_{0} = {A}_{o} cos {ω}_{o} t = {A}_{o} \frac{{e}^{j {ω}_{o} t} + {e}^{- j {ω}_{o} t}}{2} \qquad [ Equation 2 ]$$

In addition, a second voltage value Vᵣ corresponding to the second frequency generated by the second frequency generator 172 is expressed as the following Equation 3.

$${V}_{r} = {A}_{r} cos {ω}_{r} t = {A}_{r} \frac{{e}^{j {ω}_{r} t} + {e}^{- j {ω}_{r} t}}{2} \qquad [ Equation 3 ]$$

The difference frequency generator 173 is connected to the first frequency generator 171 and the second frequency generator 172, and outputs the difference value corresponding to the difference between a first frequency generated by the first frequency generator 171 and a second frequency generated by the second frequency generator 172.

At this time, a difference value V_{dmod} generated in the difference frequency generator 173 is expressed as the following Equation 4.

$${V}_{dmod} = \frac{{A}_{o} {A}_{c}}{2} ( 1 + \frac{{e}^{j {ω}_{r} t} + {e}^{- j {ω}_{r} t}}{2} ) \qquad [ Equation 4 ]$$

Here, the reason why the difference value is equal to Equation 4 is that when the object is not present on the sensing region of the object detection sensor 200, the first frequency generated by the first frequency generator 171 and the second frequency generated by the second frequency generator 172 have the same value.

The filter 174 filters an output value generated by the difference frequency generator 173, and outputs the filtered output value.

At this time, the filter 174 has a filtering region corresponding to a frequency range of a predetermined size, and filters the output value of the difference frequency generator 173 in the filtering region.

Here, the filtering region may be determined by a type of the filter 174 and change characteristics of the carbon micro-coil appearing when an object approaches on the sensing region.

The change characteristics of the carbon micro-coil will be described in more detail below.

Meanwhile, the type of the filter 174 may be determined by a structure of the carbon micro-coil.

That is, the inductance value of the carbon micro-coil does not change within a large range according to approach of the object, but changes finely, and when the first frequency generated by the first frequency generator 171 is not greatly different from the second frequency generated by the second frequency generator 172 according to the finely changing value, the filter 174 may be configured as a low-pass filter.

In addition, when the first frequency generated by the first frequency generator 171 is greatly different from the second frequency generated by the second frequency generator 172 according to the change in the inductance value of the carbon micro-coil, the filter 174 may be configured as a band-pass filter.

In other words, the type of the filter 174 may be determined by a structure such as an area of the carbon micro-coil configuring the object detection sensor 200.

The analog-to-digital converter 175 converts the output value output via the filter 174 into a digital value, and outputs the digital value.

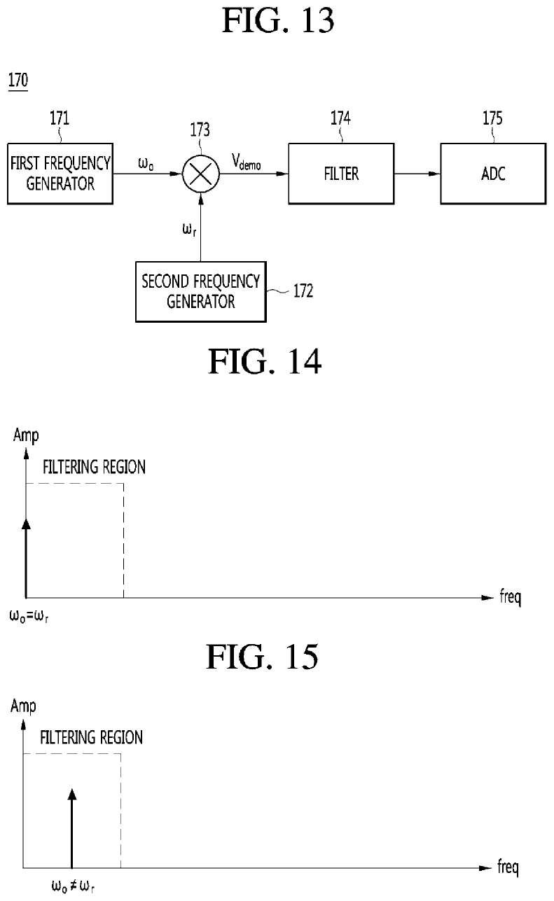

FIGS. 14 to 16 are views showing a change in a difference frequency value according to a first embodiment of the present invention.

Referring to FIG. 14, when an object is not present on the sensing region, the first frequency generated by the first frequency generator 171 and the second frequency generated by the second frequency generator 172 may have the same frequency.

Accordingly, in a general situation as described above, the output value filtered by the filter 174 according to the output value output from the difference frequency generator 173 is approximately at the DC voltage level.

In addition, referring to FIG. 15, as an object approaches on the sensing region, a frequency-shift of an output value filtered by the filter 174 occurs within a predetermined filtering region.

In other words, when a change in the inductance value of the carbon micro-coil occurs as the object approaches, a change in the first frequency generated by the first frequency generator 171 occurs, and accordingly, there is a difference between the first frequency and the second frequency.

At this time, the difference frequency between the first frequency and the second frequency increases as the approach distance of the object is closer.

Accordingly, in an embodiment of the present invention, whether the object approaches or not and the approach distance may be measured according to the value of the difference frequency between the first frequency and the second frequency. In other words, in the embodiment of the present invention, whether the object approaches or not and the approach distance are measured according to a change amount of a frequency domain according to the signal output from the filter 174.

In addition, in an embodiment, the filtering region of the filter 174 is determined according to change characteristics of the carbon micro-coil generated by a foreign substance and an object such as the human body, and it is possible to selectively measure a distance to the object only when a difference between the first frequency and the second frequency occurs in the determined filtering region.

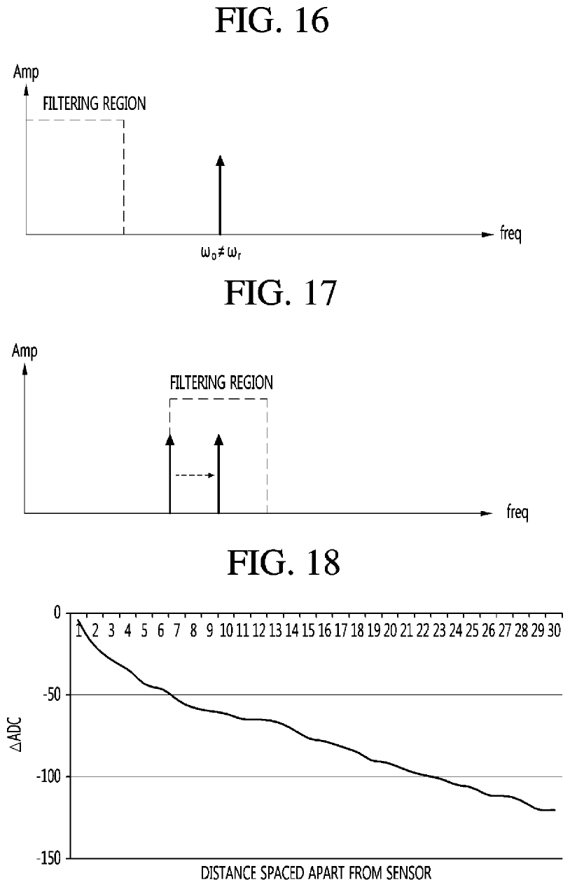

Referring to FIG. 16, when a difference between the first frequency and the second frequency is not caused by an approach of an object such as the human body but is caused by a foreign substance, the difference frequency may have a frequency that is out of the filtering region of the filter 174.

At this time, since the difference frequency is not included in the filtering region as shown in FIG. 16, in this case, whether the object approaches or not and the approach distance may not be measured.

FIG. 17 is a view showing a change in a difference frequency value according to a second embodiment of the present invention.

Referring to FIG. 17, there is a difference between the first frequency and the second frequency as an object approaches due to a design of the object detection sensor 200, and when a degree of increase or decrease of the first frequency is large according to the approach distance of the object, the filter 174 may be configured as a band-pass filter.

At this time, the filtering region of the filter 174 may have a frequency range different from that of a case configured as the low-pass filter.

In addition, whether the object approaches or not and the approach distance may be measured according to a degree of movement of the difference frequency occurring in accordance with the change of the difference frequency in the filtering region.

At this time, when the filter 174 is a band-pass filter, an output value of the difference frequency generator 173 is expressed as the following Equation 5.

$${V}_{dmod} = \frac{{A}_{o} {A}_{c}}{2} ( \frac{{e}^{j Δt} + {e}^{- j Δt}}{2} + \frac{{e}^{j 2 ( ω + Δ ) t} + {e}^{- j 2 ( ω + Δ ) t}}{2} ) \qquad [ Equation 5 ]$$

FIG. 18 is a graph showing change characteristics of a carbon micro-coil according to an embodiment of the present invention.

Referring to FIG. 18, an output value of the processor 170 may vary depending on whether an object is present or not on a sensing region of the object detection sensor 200 and an approach degree of the object.

That is, when an approach distance is divided into steps and an output value of the processor 170 is examined according to the approach distance, it may be confirmed that the output value decreases more significantly as the approach distance is closer.

That is, a decrease rate of the output value is the smallest in a first step in which the approach distance is the farthest, and a decrease rate of the output value is the largest in a 30th step in which the approach distance is the closest.

Accordingly, in the present invention, whether the object approaches or not and the approach distance may be calculated by using the output value of the processor 170, and accordingly, a driving condition of the window 730 may be determined.

That is, when the approach of the object is sensed, a driving speed of the window 730 is decreased, and when the approach distance of the object is decreased to a predetermined threshold value or less, the driving of the window 730 may be stopped.

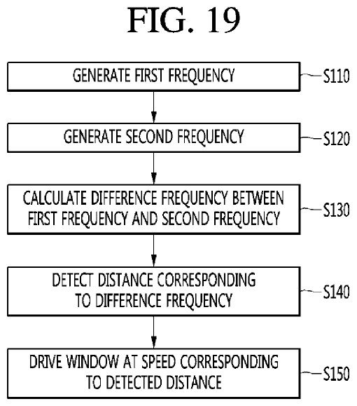

FIG. 19 is a flowchart showing steps of an operation method of a window 730 according to an embodiment of the present invention.

Referring to FIG. 19, first, a first frequency generator 171 generates a first frequency according to an inductance value or a capacitance value of a carbon micro-coil configuring an object detection sensor 200 (Step 110).

Then, a second frequency generator 172 generates a second frequency corresponding to a predetermined reference oscillation frequency (step 120).

Subsequently, a difference frequency generator 173 receives the first frequency generated by the first frequency generator 171 and the second frequency generated by the second frequency generator 172, and accordingly, outputs a difference frequency between the first frequency and the second frequency (step 130).

Accordingly, a filter 174 filters the output difference frequency to determine whether the difference frequency is present in a predetermined filtering region. In addition, when the difference frequency is present within the predetermined filtering region, an analog-to-digital converter 175 generates and outputs an output value corresponding to the difference frequency. Further, a control unit receives the output value which is output, and calculates whether an object approaches or not and an approach distance based on the received output value (step 140).

Meanwhile, when the received difference frequency is not present in the predetermined filtering region, the filter 174 does not output an output value corresponding to the received difference frequency, thereby ignoring the received difference frequency. This is because a change in impedance of the object detection sensor 200 is due to a contact of a foreign substance.

Thereafter, the processor 170 outputs a driving signal for driving a window 730 based on the output value as described above (step 150).

According to an embodiment of the present invention, a sensor applied a contact type carbon micro-coil (CMC) is applied to accurately detect an object, thereby preventing a safety accident by controlling an operation of a window of a vehicle.

In addition, according to an embodiment of the present invention, it is possible to increase a degree of freedom in an attachment position and area of a sensor by providing a low-cost, a slim thickness, and flexible type sensor in comparison with a conventional optical sensor.

In addition, according to an embodiment of the present invention, a conventional proximity sensor has a low accuracy in sensing objects other than metal and has a short detection distance, but a sensor of the present invention has an advantage that an accuracy for non-metals and human bodies is high.

Meanwhile, an object detection sensor of the present invention may be applied not only to a vehicle but also to a subway opening and closing safety door, an elevator proximity sensor, a rotary door safety sensor, and the like, and may also be used as a substitute sensor for a distance sensor in a signature refrigerator.

The characteristics, structures and effects described in the embodiments above are included in at least one embodiment but are not limited to one embodiment. Furthermore, the characteristic, structure, and effect illustrated in each embodiment may be combined or modified for other embodiments by a person skilled in the art. Thus, it should be construed that contents related to such a combination and such a modification are included in the scope of the present invention.

Further, embodiments are mostly described above. However, they are only examples and do not limit the present invention. One of ordinary skilled in the art may appreciate that several variations and applications not presented above may be made without departing from the essential characteristic of embodiments. For example, each component specifically represented in the embodiments may be varied. In addition, it should be construed that differences related to such a variation and such an application are included in the scope of the present invention defined in the following claims.

1. An object detection sensor comprising:
a sensing layer including a resin and a carbon micro-coil in the resin; and
a plurality of sensing electrodes disposed in the sensing layer,
wherein in the sensing layer, an impedance value is changed as an object approaches in a pre-set sensing region based on a reference impedance value.

2. The object detection sensor of claim 1, further comprising:
a substrate on which the sensing layer and the sensing electrode are disposed; and
a protective layer surrounding the substrate, the sensing layer, and the sensing electrode.

3. The object detection sensor of claim 1, further comprising an elastic member including an insertion groove in which the sensing layer is inserted,
wherein the elastic member is inserted into a window frame of a door body.

4. The object detection sensor of claim 3, wherein the resin is a rubber resin of the elastic member inserted into the window frame of the door body, and
the sensing layer is the elastic member in which the carbon micro-coil is dispersedly disposed in the rubber resin.

5. The object detection sensor of claim 3, wherein the sensing electrode includes a copper wire inserted into the sensing layer.

6. The object detection sensor of claim 1, wherein the impedance value of the sensing layer decreases based on the reference impedance value as a target object approaches in the sensing region, and increases based on the reference impedance value as a foreign substance, not the target object, contacts with the sensing layer.

7. The object detection sensor of claim 1, wherein the carbon micro-coil is disposed in the sensing layer in a content of 0.1 to 10 wt %.

8. The object detection sensor of claim 1, wherein a thickness of the sensing layer is in a range of 100 μm to 20 mm.

9. The object detection sensor of claim 2, wherein a ratio of an area of an upper surface of the sensing electrode to that of the substrate is in a range of 1% to 50%.

10. The object detection sensor of claim 2, wherein the sensing electrode has a thickness in a range of 25 μm to 2 mm.

11. The object detection sensor of claim 2, wherein the sensing electrode is in plural and includes a first partition wall portion disposed on the substrate and surrounding one of the plurality of sensing electrodes and a second partition wall portion disposed on the substrate and surrounding the other one of the plurality of sensing electrodes, and
wherein the sensing layer includes a first sensing layer disposed in the first partition wall portion and a second sensing layer disposed in the second partition wall portion and physically separated from the first sensing layer.

12. A vehicle safety device comprising:
a door body;
a window disposed in the door body; and
a sensor disposed on the door body for sensing an object existing on an opening and closing path of the window,
wherein the sensor includes a sensing layer including a resin and a carbon micro-coil in the resin and a sensing electrode buried into the sensing layer, and
in the sensing layer, an impedance value is changed as the object approaches on the opening and closing path based on a reference impedance value.

13. The vehicle safety device of claim 12, wherein the sensor further includes a substrate on an upper surface of which the sensing layer and the sensing electrode are disposed, and a protective layer surrounding the substrate, the sensing layer, and the sensing electrode.

14. The vehicle safety device of claim 13, wherein the sensor further includes an elastic member inserted into a window frame of the door body, and
the sensing layer configuring the sensor is inserted into an insertion groove of the elastic member.

15. The vehicle safety device of claim 14, wherein the resin configuring the sensing layer is a rubber resin of the elastic member inserted into the window frame of the door body, and
the sensing layer forms the elastic member by mixing the carbon micro-coil in the rubber resin.

16. The vehicle safety device of claim 14, wherein the sensing electrode includes a copper wire inserted into the sensing layer.

17. The vehicle safety device of claim 12, further comprising a driving condition determining unit for determining a driving condition of the window based on a change in the impedance value,
wherein the impedance value of the sensing layer decreases based on the reference impedance value as a target object approaches in a sensing region of the sensor and increases based on the reference impedance value as a foreign substance contacts with the sensing layer, and the driving condition determining unit determines the driving condition of the window only when the impedance value decreases based on the reference impedance value.

18. The vehicle safety device of claim 17, wherein the driving condition determining unit decreases an opening and closing speed of the window according to a degree of decrease of the impedance value.

19. The vehicle safety device of claim 12, wherein the carbon micro-coil is included in the sensing layer in a content of 0.1 to 10 wt %, a thickness of the sensing layer is in a range of 100 μm to 20 mm, and a thickness of the sensing electrode is in a range of 25 μm to 2 mm.

20. The vehicle safety device of claim 13, wherein the sensing electrode is in plural and includes a first partition wall portion disposed on the substrate and surrounding one of the plurality of sensing electrodes and a second partition wall portion disposed on the substrate and surrounding the other one of the plurality of sensing electrodes, and
wherein the sensing layer includes a first sensing layer disposed in the first partition wall portion and a second sensing layer disposed in the second partition wall portion and physically separated from the first sensing layer.
